(19) United States
(12) Patent Application Publication
(10) Pub. No.: US 2003/0231367 A1
(43) Pub. Date: Dec. 18, 2003

(54) Document image capture device with integrated document display screen

(76) Inventor: Angelica Quintana, Fort Collins, CO (US)

Correspondence Address: HEWLETT-PACKARD COMPANY, Intellectual Property Administration, P.O. Box 272400, Fort Collins, CO, 80527-2400, US

(21) Appl. No.: 10/160,484

(22) Filed: May 31, 2002

(51) Int. Cl. H04N 1/04; G03F 3/10

(52) U.S. Cl. 358/527; 358/474

(57) ABSTRACT

A document imaging device comprises a housing, and a document display screen disposed in the housing and operable to display a digitally scanned image of a document generated by a document imaging mechanism. A method of scanning a document using a document imaging device comprising making a preview scan and generating a scanned image of the document, and displaying the scanned image in a document display screen integrally disposed in the document imaging device.

### TECHNICAL FIELD OF THE INVENTION

The present invention relates generally to the field of imaging devices, and more particularly to a document image capture device with an integrated document display screen.

### BACKGROUND OF THE INVENTION

Document image capture devices such as scanners, multi-function devices, copiers, network senders and the like have long been equipped with a small LCD (liquid crystal display) screen generally used to display the operating status of the device. These LCD screens are typically capable of displaying one or two character lines such as the “ready” operational status or a facsimile number destination for sending the captured document image. In some handheld pen-shaped models designed for capturing text, the integrated LCD screen is capable of displaying an icon-based operating menu or several (heretofore six to seven) lines of scanned text. These text-capturing portable devices generally use optical character recognition software to “read” the text, which is then stored and transferred as editable text to a computer. Some devices are operable to display a final scan of an image or a thumbnail of an image stored on portable storage media. In all of these above-described devices, the captured text or images are transferred to a computer for viewing on the computer monitor screen prior to performing a final scan, printing, sending, or storing the scanned document.

### SUMMARY OF THE INVENTION

In accordance with an embodiment of the present invention, a document imaging device comprises a housing, and a document display screen disposed in the housing and operable to display a digitally scanned image of a document generated by a document imaging mechanism.

In accordance with another embodiment of the invention, an imaging device comprises a housing, an imaging plate disposed in the housing and adapted to receive a document, a cover coupled to the housing and adapted to cover the imaging plate, and a document display screen disposed in the cover and operable to display a captured image of the document.

In accordance with yet another embodiment of the present invention, a method of scanning a document using a document imaging device comprises the steps of making a preview scan and generating a scanned image of the document, and displaying the scanned image of the document in a document display screen integrally disposed in the document imaging device.

### BRIEF DESCRIPTION OF THE DRAWINGS

For a more complete understanding of the present invention, the objects and advantages thereof, reference is now made to the following descriptions taken in connection with the accompanying drawings in which:

FIG. 1 is an isometric view of an embodiment of an exemplary flat bed scanner with an integrated document display screen according to the teachings of the present invention;

FIG. 2 is an isometric view of an embodiment of an exemplary combination function image capture device with an integrated document display screen according to the teachings of the present invention;

FIG. 3 is an isometric view of another embodiment of an exemplary multi-function device with an integrated document display screen according to the teachings of the present invention; and

FIG. 4 is a flowchart of an exemplary operation process of the image capture device with integrated document display screen according to the teachings of the present invention.

### DETAILED DESCRIPTION OF THE DRAWINGS

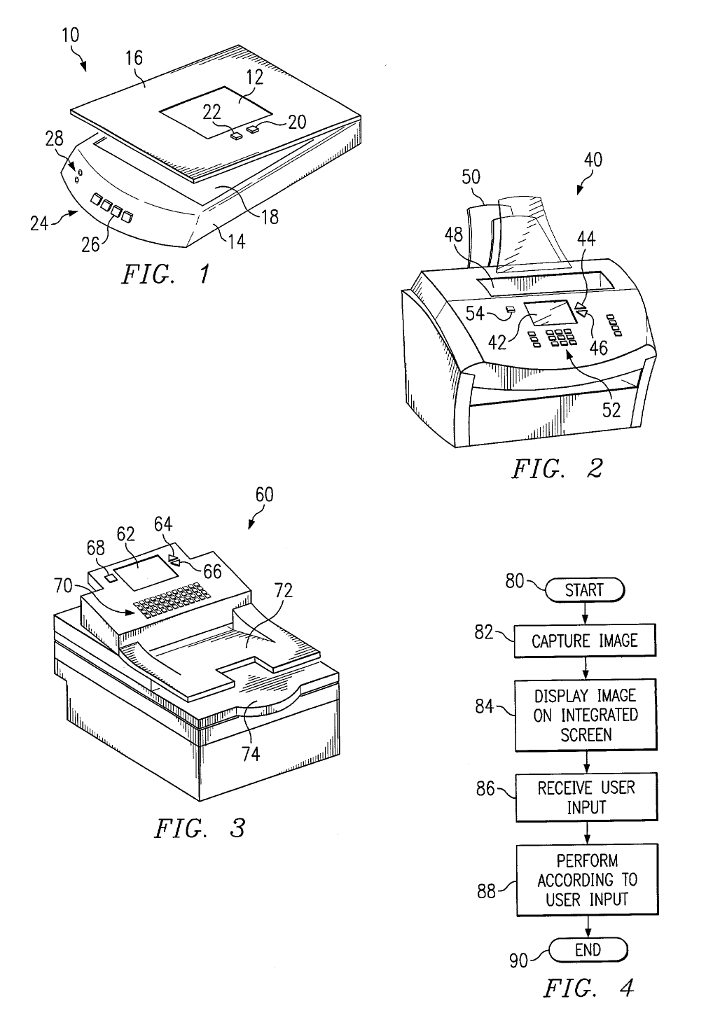

The preferred embodiment of the present invention and its advantages are best understood by referring to FIGS. 1 through 4 of the drawings, like numerals being used for like and corresponding parts of the various drawings.

FIG. 1 is an isometric view of an embodiment of an exemplary flatbed scanner 10 with an integrated document display screen 12 according to the teachings of the present invention. Flat bed scanner 10 also comprises a base 14 that houses the image capturing electronics and mechanism now known or later developed (not shown) and a hinged document lid 16 over a glass platen or imaging plate 18 disposed in base 14. Documents to be imaged such as paper documents, transparencies, photographs, and photographic negatives are generally positioned face down on imaging plate 18. Integrated document display screen 12 is sized to be capable of displaying most if not all of a captured image of a standard letter-sized document, for example. Scrolling control devices such as up and down buttons 20 and 22 may be provided to enable a user to scroll up and down the captured image so that the entire document image may be viewed using integrated document display screen 12. Scanner 10 may also display the captured document image so that its displayed size enables the entire document image to be displayed on integrated document screen 12 without scrolling. This feature may require a captured document image to be reduced to smaller-than-actual size for a large document as well as enlarged to bigger-than-actual size for a small document. For example, if scanner 10 is a photographic scanner, integrated document display screen 12 may show an enlarged scanned image of the photograph or negative for easier viewing by the user. Document display screen 12 may use one of several display technologies now known or later developed, such as liquid crystal display (LCD), thin film transistor (TFT), light emitting diodes (LED), organic polymers, touch screens, etc. Although not shown explicitly, circuitry and other hardware as well as software and firmware enabling and supporting the communication of the preview scan image to the integrated document display screen and storage media for storing the preview scan images are incorporated in scanner 10 and other embodiments of the present invention. For example, scanner 10 and other embodiments of the present invention may comprise one or more drives (not shown) for reading and writing portable storage media such as a disk, compact flash card, USB (universal serial bus) storage media, memory stick, and other forms of storage media now known or later developed.

A control panel 24 is disposed on scanner 10 to allow the user to issue operational commands such as send as facsimile, send as email, send to a storage media, and other commands. An additional and optional button 26 may be provided to enable the user to approve the scanned image, if desired. A plurality of indicator lights or LEDs 28 may be provided as further visual indication of device status.

For a flatbed-style scanner such as shown in FIG. 1, integrated document display screen 12 is incorporated in an upper surface of lid 16. The size of lid 16 makes it possible to provide a screen size that is capable of displaying a document image in its actual size or close to it. Up and down buttons 20 and 22, instead of or in addition to providing a scrolling function, may provide a zoom function. Further, buttons 20 and 22 may be used to crop the scanned image. A user may therefore manipulate the display size (zoom function) and display area (scroll function) of the captured document image to obtain a clear view of the entire document image either simultaneously or with minor manipulation. Because the user is given the opportunity to check the quality of the scanned image, the sending, storing or printing of a mis-aligned or blurry captured image is avoided.

Preferably, the processing capabilities of the on-board microprocessor (not shown) is operable to process the user's commands to zoom, scroll and crop the preview image. Further, the memory capacity of on-board memory (not shown) is appropriately sized to temporarily store the preview scan image as well as support these user functions. If desired, the resolution of the integrated document display screen 12 may be set by the user.

FIG. 2 is an isometric view of an embodiment of an exemplary combination function image capture device 40 with an integrated document display screen 42 according to the teachings of the present invention. Device 40 comprises image capturing, transmission and printing electronics and mechanism now known or later developed (not shown). Device 40 is operable to scan a document, print the document, send the captured document image via facsimile, store the image in a storage media, and/or other functions. Device 40 comprises an integrated document display screen 42 disposed on its control panel 52 along with scroll/zoom buttons 44 and 46, and one or more control buttons 54. Integrated document display screen 42 is sized to be capable of displaying a large portion of a captured image of a standard letter-sized document. For example, the size of integrated document display screen 42 may enable the simultaneous display of at least half of the document image without scrolling. Scrolling control devices such as up and down buttons 44 and 46 may be provided to enable a user to scroll up and down the captured image so that the entire document image may be viewed using screen 42. Scanner 40 may also display the captured document image so that its displayed size enables the entire document image to be displayed on integrated document screen 12 without scrolling. This feature may require a captured document image to be reduced to smaller-than-actual size as well as enlarged to bigger-than-actual size, depending on the original document dimensions.

Control panel 52 is disposed on an exterior surface on the housing of combination scanner 40 to allow the user to easily view the captured image and issue operational commands such as print, send as facsimile, send as email, store the image and other commands. Control buttons 54 comprise numerical buttons to enable the user to enter a facsimile number for sending the captured image. An additional and optional button 56 may be provided to allow the user to approve the captured image, if desired. Control panel 52 may additionally comprise a plurality of indicator lights or LEDs to provide further visual indication of device operating status. Combination scanner 40 also comprises a document feed slot and pathway and one or more document output trays 50 for receiving printed outputs.

As described above, up and down buttons 44 and 46, instead of or in addition to providing a scrolling function, may provide a zoom function. A user may therefore manipulate the display size (zoom function) and display area (scroll function) of the captured document image to obtain a clear view of the entire document image either simultaneously or with minor manipulation. Because the user is given the opportunity to check the quality of the scanned image, the sending, storing or printing of a mis-aligned or blurry captured image is avoided.

FIG. 3 is an isometric view of an embodiment of another exemplary multi-function device 60 with an integrated document display screen 62 according to the teachings of the present invention. Device 60 comprises image capturing electronics and mechanism now known or later developed (not shown) and an automatic document feeder unit 63 that may be raised to reveal a glass platen or imaging plate (not explicitly shown). Automatic document feeder unit 63 comprises integrated document display screen 62 and a number of control buttons 64, 66 and 68 arranged on a control panel 70. Automatic document feeder unit 63 further comprises a document input tray 73 for feeding a document to be processed and a document output tray 74 for receiving the processed document.

Integrated document display screen 62 is sized to be capable of displaying most if not all of a captured image of a standard letter-sized document, for example. Scrolling control devices such as up and down buttons 64 and 66 may be provided to allow a user to scroll up and down the captured image so that the entire document image may be viewed using integrated document display screen 62. Digital sender 60 may also display the captured document image so that its displayed size enables the entire document image to be displayed on integrated document screen 62 without scrolling. This feature may require a captured document image to be reduced to smaller-than-actual size for a large document as well as enlarged to bigger-than-actual size for a small document. Control panel 70 is disposed on digital sender 60 to allow the user to issue operational commands such as send as facsimile, send as email, and other commands. An additional and optional button 68 may be provided to allow the user to approve the scanned image, if desired. Up and down buttons 64 and 66, instead of or in addition to providing a scrolling function, may provide a zoom function. A user may therefore manipulate the display size (zoom function) and display area (scroll function) of the captured document image to obtain a clear view of the entire document image either simultaneously or with minor manipulation. The user may further use buttons 64 and 66 to crop the captured image. Because the user is given the opportunity to check the quality of the scanned image, the sending, storing or printing of a mis-aligned or blurry captured image is avoided.

FIG. 4 is a flowchart of an exemplary operation process 80 of the image capture device with an integrated document display screen according to the teachings of the present invention. The user first positions or feeds the document so that the image capture device may scan the correct side of the document and generate a captured image, as shown in block 82. The captured document image is then displayed on the integrated document display screen, as shown in block 84. The integrated document display screen is capable of simultaneously displaying most if not all of the captured document image. The user may scroll up and down the captured document image if not all of the captured image is displayed simultaneously on the screen, as shown in block 86. Further, the user may zoom in and out of the captured document image to allow a viewing of most or all of the document image, or focus on a certain portion of the document image. User input may further include an indication of approval of the scanned image, send the captured image as a facsimile, send the captured image as an email attachment, store the captured image, print the captured image, etc. In block 88, the image capture device performs as instructed by the user, including scrolling, cropping and/or zooming, and also the sending and printing functions. The process ends in block 90.

Unlike conventional devices, an image capture device incorporating an integrated document display screen does not have the added expense and bulk of a computer that is typically connected to the image capture device to enable a display of a preview scan image. Embodiment of the image capture device can then be standalone while still enabling the user to verify that the captured image is not skewed, blurry or otherwise undesirable. Furthermore, unlike the status text screen of conventional devices, the integrated document display screen is capable of displaying the captured image of documents, either in its entirety simultaneously or a substantial portion thereof.

What is claimed is:

1. A document imaging device, comprising:
a housing; and
a document display screen disposed in the housing and operable to display a digitally scanned image of a document generated by a document imaging mechanism.

2. The device, as set forth in claim 1, wherein the document display screen is sized to display at least a substantial portion of the digital scanned image of the document.

3. The device, as set forth in claim 1, further comprising a document scrolling device disposed in the housing and the actuation of which scrolls up or down the digitally scanned image of the document in the document display screen.

4. The device, as set forth in claim 1, further comprising a document zooming device disposed in the cover and the actuation of which zooms in or out of the digitally scanned image of the document in the document display screen.

5. The device, as set forth in claim 1, further comprising a document cropping device disposed in the cover and the actuation of which indicates a portion of the digitally scanned image of the document displayed in the document display screen that is to be deleted.

6. The device, as set forth in claim 1, wherein the document display screen is a liquid crystal display.

7. The device, as set forth in claim 1, wherein the digitally scanned image of the document is a preview scan image.

8. The device, as set forth in claim 1, wherein the device selected from the group consisting of a scanner, facsimile machine, multi-function device, and a copier.

9. An imaging device, comprising:
a housing;
an imaging plate disposed in the housing and adapted to receive a document;
a cover coupled to the housing and adapted to cover the imaging plate; and
a document display screen disposed in the cover and operable to display a captured image of the document.

10. The imaging device, as set forth in claim 9, wherein the document display screen is sized to display at least a substantial portion of the captured image of the document.

11. The imaging device, as set forth in claim 9, further comprising a document scrolling device the actuation of which scrolls up or down the captured image of the document depicted on the document display screen.

12. The imaging device, as set forth in claim 9, further comprising a document zooming device the actuation of which zooms in or out of the captured image of the document depicted on the document display screen.

13. The imaging device, as set forth in claim 9, further comprising a document cropping device the actuation of which indicates a portion of the digitally scanned image of the document displayed in the document display screen that is to be deleted.

14. The imaging device, as set forth in claim 9, wherein the document display screen is a liquid crystal display.

15. The imaging device, as set forth in claim 9, wherein the captured image of the document is a preview scan image.

16. The imaging device, as set forth in claim 9, wherein the imaging device is selected from a group consisting of a scanner, facsimile machine, multi-function device, and copier.

17. A method of scanning a document using a document imaging device, comprising:
making a preview scan and generating a scanned image of the document; and
displaying the scanned image of the document in a document display screen integrally disposed in the document imaging device.

18. The method, as set forth in claim 17, further comprising making a final scan and generating a final scanned image of the document.

19. The method, as set forth in claim 17, further comprising sending the scanned image of the document in an email.

20. The method, as set forth in claim 17, further comprising sending the scanned image of the document as a facsimile.

21. The method, as set forth in claim 17, further comprising printing the scanned image of the document.

22. The method, as set forth in claim 17, further comprising storing the scanned image of the document in a storage media.

23. An article of manufacture comprising:
a computer-readable medium having encoded thereon a method of scanning a document, comprising:
making a preview s can and generating a scanned image of the document; and
displaying the scanned image of the document in a document display screen integrally disposed in a document imaging device.

24. A document imaging device, comprising:
a computer-readable medium having encoded thereon a method of scanning a document, comprising:
computer-readable program code means for making a preview scan and generating a scanned image of the document;
computer-readable program code means for displaying the scanned image of the document in a document display screen integrally disposed in the document imaging device; and
computer-readable program code means for performing a number of functions operating on the scanned image of the document displayed on the document display screen.
